(19) United States
(12) Patent Application Publication
(10) Pub. No.: US 2018/0315808 A1
(43) Pub. Date: Nov. 1, 2018

(54) ORGANIC LIGHT EMITTING (OLED) DISPLAY PANELS, AND THE MANUFACTURING METHODS AND DISPLAY DEVICES THEREOF

(71) Applicant: SHENZHEN CHINA STAR OPTOELECTRONICS TECHNOLOGY CO., LTD., Shenzhen, Guangdong (CN)

(72) Inventor: Baixiang HAN, Shenzhen, Guangdong (CN)

(73) Assignee: Shenzhen China Star Optoelectronics Technology Co., Ltd., Shenzhen, Guangdong (CN)

(21) Appl. No.: 15/541,646

(22) PCT Filed: Jun. 15, 2017
(86) PCT No.: PCT/CN2017/088359

§ 371 Date: Jul. 5, 2017

(30) Foreign Application Priority Data
Apr. 28, 2017 (CN) 201710295368.9

(51) Int. Cl. H01L 27/32

(52) U.S. Cl. CPC H01L 27/3272; H01L 27/322; H01L 27/1225; H01L 27/3262; H01L 2227/323; H01L 27/3246

(57) ABSTRACT

The present disclosure relates to an OLED display panel and the manufacturing method and the display device thereof. The method includes: forming a plurality of film layers on a surface of a first substrate, the film layers comprises a buffer layer and a semiconductor oxide pattern layer arranged on the buffer layer; arranging a second substrate on the film layers; forming a masking layer on a bottom surface of the first substrate, the masking layer corresponding to the semiconductor oxide pattern layer. By configuring the masking layer on the bottom surface of the first substrate, the semiconductor oxide pattern layer is masked. The metal masking layer is removed so as to avoid the parasitic capacitance generated by the metal masking layer.

### BACKGROUND OF THE INVENTION

### 1. Field of the Invention

The present disclosure relates to display technology, and more particularly to an organic light emitting (OLED) display panel, and the manufacturing method and the display device thereof.

### 2. Discussion of the Related Art

Currently, the semiconductor oxide thin film transistor (TFT) of the top gate structure has a smaller parasitic capacitance. As the TFT size can be smaller, and thus it has become a preferable choice for the OLED. However, the characteristic of the semiconductor oxide may be changed when being exposed to external light beams, which may affect the TFT performance.

Conventionally, a metal masking layer is arranged in the location of the TFT trench layer corresponding to the semiconductor oxide to prevent the semiconductor oxide from being exposed to the external light beams. However, the metal masking layer and the TFT may cooperatively form the parasitic capacitance, which may also affect the TFT performance.

### SUMMARY

The present disclosure relates to an OLED display panel and the manufacturing method and the display device thereof to overcome the above-mentioned issue regarding the parasitic capacitance.

In one aspect, a manufacturing method of organic light emitting diode (OLED) display panels includes: forming a plurality of film layers on a surface of a first substrate, the film layers includes: a buffer layer and a semiconductor oxide pattern layer arranged on the buffer layer; arranging a second substrate on the film layers; forming a masking layer on a bottom surface of the first substrate, the masking layer corresponding to the semiconductor oxide pattern layer; wherein the step of forming a masking layer on a bottom surface of the first substrate further includes: printing light-absorbing material on the bottom surface of the first substrate to form the masking layer; or forming a thin film layer by the light-absorbing material, and adhering the thin film layer on the polarizer; adhering the polarizer to the bottom surface of the first substrate, and configuring a location of the light-absorbing material of the thin film layer to be correspond to the semiconductor oxide pattern layer.

In another aspect, an OLED display panel includes: a first substrate configured with a plurality film layers on a surface, the film layers comprising a buffer layer and a semiconductor oxide pattern layer arranged on the buffer layer; a second substrate on the film layers; wherein a masking layer is configured on a bottom surface of the first substrate, and the he masking layer corresponds to the semiconductor oxide pattern layer.

In view of the above, the film layers are formed on the surface of the first substrate. The film layers includes the buffer layer and the semiconductor oxide patterned layer. The second substrate is arranged on the film layers. The masking layer is formed on the bottom surface of the first substrate. When the masking layer blocks the light beams subject to the semiconductor oxide patterned layer, the metal masking layer is removed at the same time, which reduces the parasitic capacitance generated by the metal masking layer.

### BRIEF DESCRIPTION OF THE DRAWINGS

FIG. 1 is a flowchart of the manufacturing method of the OLED display panel in accordance with one embodiment of the present disclosure.

FIG. 2 is a schematic view of the OLED display panel formed by the steps in FIG. 1.

FIG. 3 is a schematic view showing the step S11 in FIG. 1.

FIG. 4 is a schematic view showing the step S13 in FIG. 1.

FIG. 5 is a schematic view showing the step S113 in FIG. 1.

FIG. 6 is a schematic view showing the step S13 in FIG. 1.

FIG. 7 is a schematic view of the thin film layer in FIG. 6.

### DETAILED DESCRIPTION OF THE EMBODIMENTS

Embodiments of the invention will now be described more fully hereinafter with reference to the accompanying drawings, in which embodiments of the invention are shown.

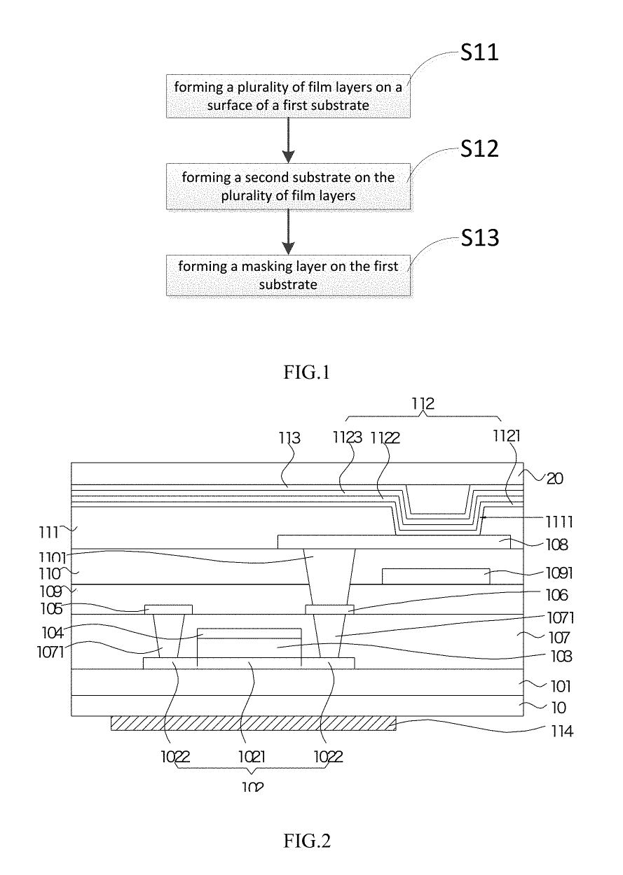

Referring to FIGS. 1 and 2, the manufacturing method of the OLED display panel includes the following steps.

In step S11: forming a plurality of film layers on a surface of a first substrate 10.

The film layers includes a buffer layer 101 and a semiconductor oxide pattern layer 102 arranged on the buffer layer 101.

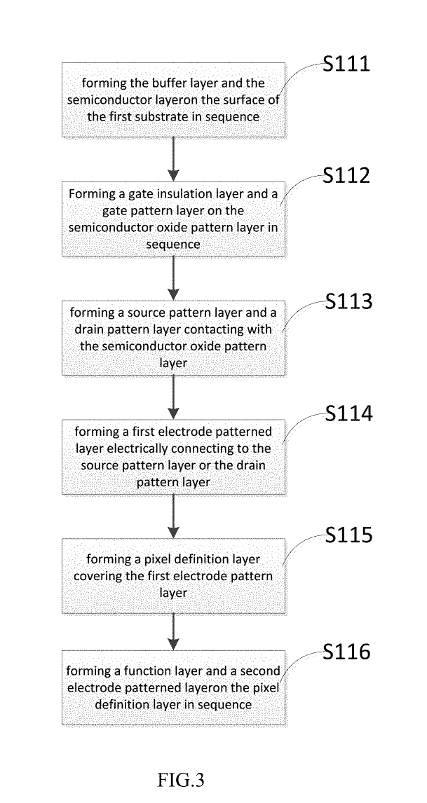

Referring to FIG. 3, the step S11 further includes the steps S111-S113.

In the step S111, forming the buffer layer 101 and the semiconductor layer 102 on the surface of the first substrate 10 in sequence.

Specifically, after the first substrate 10 is cleaned, a layer of silicon oxide may be deposited on the first substrate 10 as a buffer layer by physical vapor deposition or plasma vapor deposition. Alternatively, depositing a layer of silicon nitride layer, and then continuing to deposit a layer of silicon oxide layer on the silicon nitride layer to collectively serve as a buffer layer 101. In this way, the semiconductor oxide layer is deposited on the buffer layer 101. After the lithography processes, including photoresist coating, exposure, development and peeling, a patterned semiconductor oxide layer is formed, i.e., a semiconductor oxide pattern layer 102.

The semiconductor oxide pattern layer 102 includes a first portion 1021 and a second portion 1022 adjacent to the first portion 1021. In an example, the second portion 1022 is arranged at two opposite sides of the first portion 1021.

Alternatively, the first substrate 10 is a glass substrate or a silicon substrate, and the semiconductor oxide is IGZO, i.e., indium gallium zinc oxide.

In step S112, forming a gate insulation layer 103 and a gate pattern layer 104 on the semiconductor oxide pattern layer 102 in sequence.

Alternatively, a silicon oxide layer covering the semiconductor oxide pattern layer 102 is also deposited on the buffer layer 101. After the lithography processes, including photoresist coating, exposure, development and peeling, the gate insulation layer 103 corresponding to the first portion 1021 of the semiconductor oxide pattern layer 102 is formed on the semiconductor oxide pattern layer 102. Afterward, a metal layer is deposited, and then the lithography processes, including photoresist coating, exposure, development and peeling, may be conducted to form the patterned metal layer serving as the gate pattern layer 104.

In an example, the metal layer is a molybdenum, aluminum or copper metal layer.

Further, the semiconductor oxide pattern layer 102 is applied with the annealing method of hydrogen plasma or argon plasma. During the annealing process, the second portion 1022 of the semiconductor oxide pattern layer 102 possesses the conductive characteristics. The first portion 1021 is configured to be opposite to the gate insulation layer 103, and may preserve the conductive characteristics after the annealing process due to the gate insulation layer 103. It can be understood that the same process for preserving the conductive characteristics of the second portion 1022 of the semiconductor oxide pattern layer 102 may be conducted in other steps.

In step S113, forming a source pattern layer 105 and a drain pattern layer 106 contacting with the semiconductor oxide pattern layer 102.

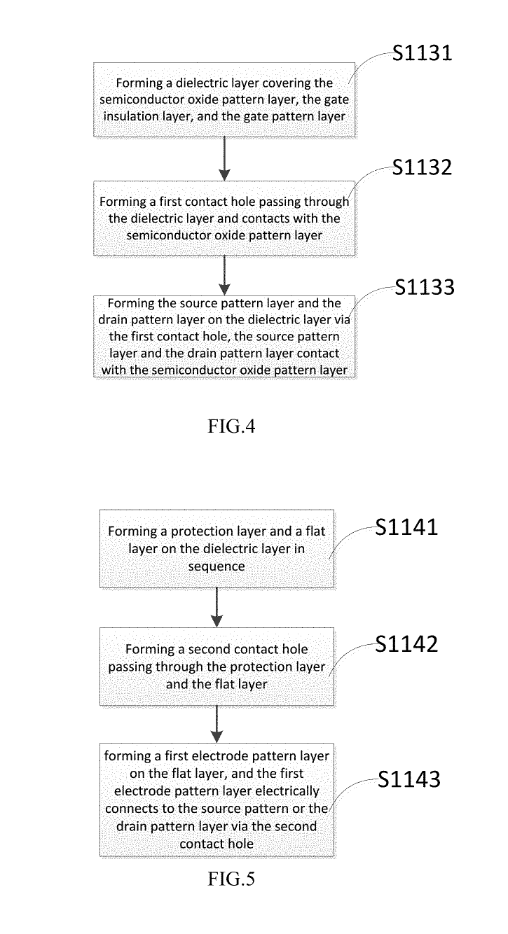

Referring to FIG. 4, the step S113 further includes:

In step S1131: forming a dielectric layer 107 covering the semiconductor oxide pattern layer 102, the gate insulation layer 103, and the gate pattern layer 104.

Specifically, the dielectric layer 107 may be formed by physical vapor deposition or chemical vapor deposition. The dielectric layer 107 may be of a single-layer or of a dual-layer structure made by silicon oxide or silicon nitride.

In step S1132, forming a first contact hole 1071 passing through the dielectric layer 107 and contacts with the semiconductor oxide pattern layer 102.

Specifically, the first contact hole 1071 is formed on the dielectric layer 107 by processes, such as coating or exposure, and the patterned first contact hole 1071 is etched. After the peeling process, the first contact hole 1071 may be obtained.

In one example, the first contact hole 1071 connects to the second portion 1022 of the semiconductor oxide pattern layer 102.

In step S1133, forming the source pattern layer 105 and the drain pattern layer 106 on the dielectric layer 107 via the first contact hole 1071, the source pattern layer 105 and the drain pattern layer 106 contact with the semiconductor oxide pattern layer 102.

Specifically, the metal layer is deposited on the dielectric layer 107 and within the first contact hole 1071, and a photoresist layer is deposited on the metal layer. Afterward, the processes, such as exposure, development, etching and peeling, may be applied to obtain the patterned metal layer serving as the source pattern layer 105 and the drain pattern layer 106. As the first contact hole 1071 connects to the second portion 1022 of the semiconductor oxide pattern layer 102, the source pattern layer 105 and the drain pattern layer 106 contact with the second portion 1022 of the semiconductor oxide pattern layer 102.

In step S114: forming a first electrode patterned layer 108 electrically connecting to the source pattern layer 105 or the drain pattern layer 106.

Referring to FIG. 5, the step S114 may also include the following sub-steps.

In step S1141, forming a protection layer 109 and a flat layer 110 on the dielectric layer 107 in sequence, wherein the protection layer 109 is configured with a color filter layer 1091. The flat layer 110 is arranged on the protection layer 109, and the flat layer 110 covers the color filter layer 1091.

In step S1142, forming a second contact hole 1101 passing through the protection layer 109 and the flat layer 110, and the second contact hole 1101 connects to the source pattern layer 105 or the drain pattern layer 106.

Specifically, forming the patterned contact holes on the flat layer 110 by the processes, such as coating and exposure, and the contact hole corresponds to the source pattern layer 105 and the drain pattern layer 106. Afterward, the etching process is applied to the patterned contact hole until reaching the source pattern layer 105 or the drain pattern layer 106. After the peeling process, the second contact hole 1101 connecting to the source pattern layer 105 and the drain pattern layer 106 may be obtained.

In step S1143, forming a first electrode pattern layer 108 on the flat layer 110, and the first electrode pattern layer 108 electrically connects to the source pattern layer 105 or the drain pattern layer 106 via the second contact hole 1101.

Specifically, the physical vapor deposition may be adopted to form the metal layer on the flat layer 110 and the second contact hole 1101. The photoresist layer is then deposited on the metal layer. After the manufacturing processes, such as exposure, lithography, etching and peeling, the patterned first electrode layer may be obtained. As the second contact hole 1101 connects to the source pattern layer 105 or the drain pattern layer 106, the first electrode pattern layer 108 electrically connects to the source pattern layer 105 or the drain pattern layer 106 via the second contact hole 1101.

The first electrode pattern layer 108 may be the anode layer or the cathode layer of the display panel in one embodiment.

In step S115, forming a pixel definition layer 111 covering the first electrode pattern layer 108.

The pixel definition layer 111 is configured with a pixel emission area 1111.

Specifically, the pixel definition layer 111 is formed on the flat layer 110 via physical or chemical vapor deposition. The pixel emission area 1111 is formed on the pixel definition layer 111 via the lithography processes, including photoresist coating, exposure, development and peeling. The pixel emission area 1111 corresponds to the color filter layer 1091.

In step S116, forming a function layer 112 and a second electrode patterned layer 113 on the pixel definition layer 111 in sequence. The function layer 112 and the second electrode patterned layer 113 are configured in accordance with the pixel emission area 1111.

Specifically, forming an electron transmission layer 1121, an emission layer 1122, a hole transport layer 1123, and a second electrode pattern layer 113.

The second electrode pattern layer 113 electrically connects to the first electrode pattern layer 108, and a polarity of the second electrode pattern layer 113 is opposite to the polarity of the first electrode pattern layer 108.

In step S12, forming a second substrate 20 on the plurality of film layers.

Specifically, the first substrate 10 and the second substrate 20 are bonded with each other after the film layers are formed on the first substrate 10.

In step S13, forming a masking layer 114 on the first substrate 10, wherein the masking layer 114 corresponds to the semiconductor oxide pattern layer 102.

The masking layer 114 may be by two methods. First, light-absorbing material is printed on a bottom surface of the first substrate 10, and the location of the light-absorbing material, such as black materials, corresponds to the semiconductor oxide pattern layer 102. When the black materials are irradiated, the light beams are blocked and thus the light beams cannot arrive the semiconductor oxide pattern layer 102.

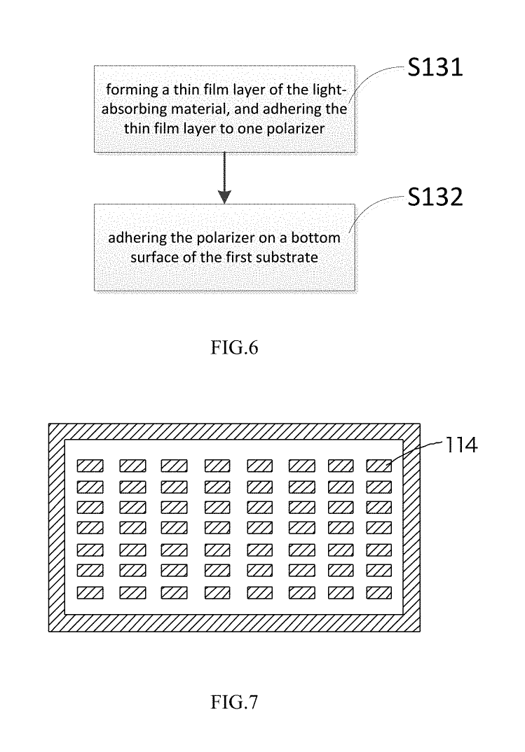

Referring to FIG. 6, the second method includes the following steps.

In step S131, forming a thin film layer of the light-absorbing material, and adhering the thin film layer to one polarizer.

Generally, after the first substrate 10 are and the second substrate 20 are bonded, the polarizer is adhered to the bottom surface of the first substrate 10. In the embodiment, the thin film layer is obtained first. As shown in FIG. 7, the black materials are configured in a plurality of locations on the thin film layer, which is the masking layer 114. Afterward, the thin film layer is adhered to the polarizer.

In step S132, adhering the polarizer on a bottom surface of the first substrate 10.

Specifically, the polarizer is adhered to the bottom surface of the first substrate 10. Also, the masking layer 114 of black materials is configured according to the semiconductor oxide pattern layer 102.

In an example, the non-display area of the display panel may be printed with the black materials. Alternatively, the black materials may be printed in the locations of the thin film layer, as shown in FIG. 7, corresponding to the non-display area, so as to block the non-display area.

Referring to FIG. 2, the OLED display panel includes a first substrate 10 and the second substrate 20 opposite to the first substrate 10.

The first substrate 10 includes a plurality of film layers on a surface. The film layers includes a buffer layer 101 and a semiconductor layer 102 arranged on the semiconductor layer 102.

Further, the masking layer 114 is provided on a bottom surface of the first substrate 10. The masking layer 114 is configured according to the semiconductor oxide pattern layer 102.

The film layers and the masking layer may be manufactured by the above method.

The second substrate 20 is arranged on the film layer.

In an example, the display device includes the above display panel.

In view of the above, the film layers are formed on the surface of the first substrate. The film layers includes the buffer layer and the semiconductor oxide patterned layer. The second substrate is arranged on the film layers. The masking layer is formed on the bottom surface of the first substrate. When the masking layer blocks the light beams subject to the semiconductor oxide patterned layer, the metal masking layer is removed at the same time, which reduces the parasitic capacitance generated by the metal masking layer. Also, as the metal masking layer is removed, the number of manufacturing processes and the masks of the display panel is reduced. The manufacturing cost is reduced, and the efficiency is enhanced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of organic light emitting diode (OLED) display panels, comprising:
forming a plurality of film layers on a surface of a first substrate, the film layers comprises a buffer layer and a semiconductor oxide pattern layer arranged on the buffer layer;
arranging a second substrate on the film layers;
forming a masking layer on a bottom surface of the first substrate, the masking layer corresponding to the semiconductor oxide pattern layer;
wherein the step of forming a masking layer on a bottom surface of the first substrate further comprises:
printing light-absorbing material on the bottom surface of the first substrate to form the masking layer; or
forming a thin film layer by the light-absorbing material, and adhering the thin film layer on the polarizer;
adhering the polarizer to the bottom surface of the first substrate, and configuring a location of the light-absorbing material of the thin film layer to be correspond to the semiconductor oxide pattern layer.

2. The method as claimed in claim 1, wherein the step of forming the film layers on the surface of the first substrate further comprises:
forming a buffer layer and a semiconductor oxide pattern layer on the surface of the first substrate in sequence;
forming a gate insulation layer and a gate pattern layer on the semiconductor oxide pattern layer in sequence;
forming a source pattern layer and a drain pattern layer contacting with the semiconductor oxide pattern layer.

3. The method as claimed in claim 2, wherein the step of forming the source pattern layer and the drain pattern layer contacting with the semiconductor oxide pattern layer further comprises:
forming a dielectric layer covering the semiconductor oxide pattern layer, the gate insulation layer, and the gate pattern layer;
forming a first contact hole passing through the dielectric layer and contacts with the semiconductor oxide pattern layer;
forming the source pattern layer and the drain pattern layer on the dielectric layer via the first contact hole, and the source pattern layer and the drain pattern layer contact with the semiconductor oxide pattern layer.

4. The method as claimed in claim 3, wherein the step of forming the film layers on the surface of the first substrate further comprises:
forming a first electrode patterned layer electrically connecting to the source pattern layer or the drain pattern layer;
forming a pixel definition layer covering the first electrode pattern layer, and the pixel definition layer being configured with a pixel emission area;
forming a function layer and a second electrode patterned layer on the pixel definition layer in sequence, the second electrode pattern layer electrically connects to the first electrode pattern layer.

5. The method as claimed in claim 4, wherein the step of forming the first electrode patterned layer electrically connecting to the source pattern layer or the drain pattern layer further comprises:
forming a protection layer and a flat layer on the dielectric layer in sequence;
forming a second contact hole passing through the protection layer and the flat layer, and the second contact hole connects to the source pattern layer or the drain pattern layer;
forming a first electrode pattern layer on the flat layer via the second contact hole, and the first electrode pattern layer electrically connects to the source pattern layer or the drain pattern layer.

6. The method as claimed in claim 5, wherein the protection layer is configured with a color filter layer corresponding to the pixel emission area.

7. An OLED display panel, comprising:
a first substrate configured with a plurality film layers on a surface, the film layers comprising a buffer layer and a semiconductor oxide pattern layer arranged on the buffer layer;
a second substrate on the film layers;
wherein a masking layer is configured on a bottom surface of the first substrate, and the he masking layer corresponds to the semiconductor oxide pattern layer.

8. The display panel as claimed in claim 7, wherein the masking layer is formed by printing light-absorbing material on the bottom surface of the first substrate.

9. The display panel as claimed in claim 7, wherein the masking layer is a thin film layer made by the light-absorbing material, wherein the a polarizer is adhered to the thin film layer, and the polarizer is adhered to the bottom surface of the first substrate, and a location of the light-absorbing material of the thin film layer correspond to the semiconductor oxide pattern layer.

10. The display panel as claimed in claim 7, wherein the film layers further comprises:
a gate insulation layer and a gate pattern layer arranged on the semiconductor oxide pattern layer in sequence;
a source pattern layer and a drain pattern layer contacting with the semiconductor oxide pattern layer.

11. The display panel as claimed in claim 10, wherein the film layers further comprises:
a dielectric layer covering the semiconductor oxide pattern layer, the gate insulation layer, and the gate pattern layer, and the dielectric layer is arranged on the buffer layer, wherein the dielectric layer comprises:
a first contact hole passing through the dielectric layer and contacts with the semiconductor oxide pattern layer;
the source pattern layer and the drain pattern layer contact with the semiconductor oxide pattern layer via the first contact hole.

12. The display panel as claimed in claim 11, wherein the film layers further comprises:
a first electrode patterned layer electrically connecting to the source pattern layer or the drain pattern layer;
a pixel definition layer covering the first electrode pattern layer, and the pixel definition layer being configured with a pixel emission area;
a function layer and a second electrode patterned layer on the pixel definition layer in sequence, and the second electrode pattern layer electrically connects to the first electrode pattern layer.

13. The display panel as claimed in claim 12, wherein the film layers further comprises:
a protection layer and a flat layer on the dielectric layer arranged on the dielectric layer in sequence;
a second contact hole passing through the protection layer and the flat layer, and the second contact hole connects to the source pattern layer or the drain pattern layer;
a first electrode pattern layer on the flat layer, and the first electrode pattern layer electrically connects to the source pattern layer or the drain pattern layer via the second contact hole.

14. The display panel as claimed in claim 13, wherein the protection layer is configured with a color filter layer, and the color filter layer corresponds to the pixel emission area.

15. A display device comprises the display panel as claimed in claim 7.
